(19) United States
(12) Patent Application Publication
(10) Pub. No.: US 2008/0009096 A1
(43) Pub. Date: Jan. 10, 2008

(54) PACKAGE-ON-PACKAGE AND METHOD OF FABRICATING THE SAME

(75) Inventor: Hyeon HWANG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/741,618

(22) Filed: Apr. 27, 2007

(30) Foreign Application Priority Data
Jul. 10, 2006 (KR) 2006-0064463

(51) Int. Cl. H01L 21/52

(52) U.S. Cl. 438/108; 438/107; 438/112; 438/118; 257/E21.5

(57) ABSTRACT

A package-on-package and a method of fabricating the same capable of increasing mounting density of a semiconductor package are provided. The method includes providing a flexible substrate first, second, and third printed circuit patterns formed on the upper and lower surfaces of the flexible substrate. First and second semiconductor chips and then respectively mounted to substantially central portions of the upper and lower surfaces of the flexible substrate and electrically connected to the first printed circuit patterns. A package body is formed by sealing the first printed circuit pattern and the semiconductor chips. Portions of the flexible substrate having the second and third printed circuit patterns are then bent towards and adhered to the upper and lower surfaces of the package body.

### CROSS-REFERENCE TO RELATED PATENT APPLICATION

This application claims the benefit of Korean Patent Application No. 10-2006-0064463, filed on Jul. 10, 2006, in the Korean Intellectual Property Office, the disclosure of which is incorporated herein in its entirety by reference.

### BACKGROUND

1. Field of the Invention

The present invention relates to a semiconductor package and a method of fabricating the semiconductor package, and more particularly, to a package-on-package with improved mounting density and a method of fabricating the package-on-package to increase the mounting density within a limited area.

2. Description of the Related Art

A system-on-chip (SOC) refers to a semiconductor chip including several different types of semiconductor devices in the semiconductor chip. It is generally very difficult to form the SOC in a wafer fabricating process. That is, a process of incorporating several different types of semiconductor devices having different functions within one semiconductor chip in the wafer fabricating process is costly and requires advanced technology. In recent years, however, a system-in-package (SIP) or a package-on-package (POP) chip has received much attention because POP or SIP makes it possible to easily form different types of semiconductor devices in one semiconductor package. This in turn makes POP or SIP advantageous over SOC in terms of cost and manufacturing ease.

With regard to utilizing SIP and POP architectures, SIPs are generally advantageous in reducing the size of a semiconductor package, while POP schemes are advantageous in stacking applications. Because mounting different semiconductor packages on one semiconductor package is often desirably to reduce the size or footprint of the packages, POP schemes are widely used in a large number of applications to solve problems occurring when stacking semiconductor chips.

### SUMMARY

The present invention provides a method of fabricating a package-on-package in which the mounting density within a limited area can be increased and semiconductor chips can be mounted on the upper and lower surfaces of a substrate.

The present invention also provides a package-on-package fabricated by the above method of fabricating a package-on-package.

According to an embodiment of the present invention, a method of fabricating a package-on-package includes providing a flexible substrate having a first printed circuit pattern formed on the upper and lower surfaces of a central portion of the flexible substrate, and having second and third printed circuit patterns respectively formed on side portions of the flexible substrate. The method also includes mounting semiconductor chips on the central portions of the upper and lower surfaces of the flexible substrate, and forming a package body by sealing the first printed circuit pattern and the semiconductor chips. Both sides of the flexible substrate having the second and third printed circuit patterns are then respectively bent toward the upper and lower surfaces of the package body, and adhered to the package body such that second and third printed circuit patterns are respectively exposed above and below the package body.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a plan view of a substrate used in a package-on-package according to an embodiment of the present invention;

FIG. 2 illustrates a cross-sectional view of a package-on-package having a semiconductor chip mounted on the substrate illustrated in FIG. 1 according to an embodiment of the present invention;

FIG. 3 illustrates a cross-sectional view of a package-on-package having semiconductor chips mounted on the substrate illustrated in FIG. 1 according to another embodiment of the present invention;

FIG. 4 illustrates a cross-sectional view of a package body formed by molding the semiconductor package illustrated in FIG. 2 according to an embodiment of the present invention;

FIG. 5 illustrates a cross-sectional view of portions of the flexible substrate having the second and third printed circuit patterns adhered to the upper and lower surfaces of a package body on a package-on-package according to an embodiment of the present invention; and

FIG. 6 illustrates a cross-sectional view of a semiconductor package and solder ball grid array adhered to a package-on-package according to an embodiment of the present invention.

### DETAILED DESCRIPTION

The present invention will now be described more fully hereinafter with reference to the accompanying drawings, in which embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to one skilled in the art. Like numbers refer to like elements throughout the specification.

A method of fabricating a package-on-package according to embodiments of the present invention will be described with reference to FIGS. 1 through 6.

FIG. 1 illustrates a plan view of a substrate used in a package-on-package 100 according to an embodiment of the present invention.

Referring to FIG. 1, a flexible substrate 102 is first prepared. The flexible substrate 102 may be a flexible printed circuit (FPC) substrate that is flexible. The flexible substrate 102 may also have portions of its upper and lower surfaces on which printed circuit patterns can be formed. Chip pads 104 may also be formed on the surfaces of the flexible substrate 102, to which semiconductor chips can be adhered. In the embodiment illustrated in FIG. 1, a first printed circuit pattern 106 is formed to provide an electrically connection point between the semiconductor chips and the flexible substrate 102. First printed circuit patterns 106 may be formed on the upper and lower surfaces of the flexible substrate 102.

The first printed circuit pattern 106 will be configured in a bond finger form when wire bonding is used for semiconductor chip connections and will be configured in a land form when flip chip bonding is used for semiconductor chip connections. The first printed circuit pattern 106 may be formed on both the upper and lower surfaces of the flexible substrate 102.

On one side (the left side as illustrated in FIG. 1) of the first printed circuit pattern 106, second printed circuit patterns 108A and 108B are also formed in a matrix arrangement. The first printed circuit pattern 106 and the second printed circuit pattern 108A are electrically connected to each other using a wire 110. The second printed circuit pattern 108A is connected to the first printed circuit pattern 106 on the upper surface of the flexible substrate 102 and the second printed circuit pattern 108B is connected to the first printed circuit pattern 106 on the lower surface of the flexible substrate 102. The second printed circuit patterns 108A and 108B may be in the form of a solder ball pad.

On the other side (the right side as illustrated in FIG. 1) of the first printed circuit pattern 106, a third printed circuit pattern 112 is also formed in a matrix arrangement. The first printed circuit pattern 106 and the third printed circuit pattern 112 are electrically connected to each other using another wire 113. The third printed circuit pattern 112 is indicated by a dotted line because the third printed circuit pattern 112 is formed on the lower surface of the flexible substrate 102.

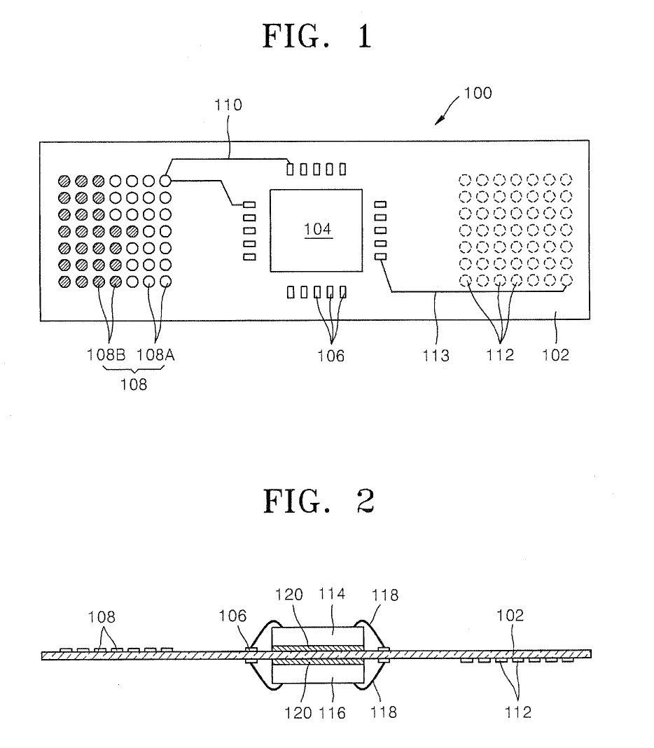

FIG. 2 illustrates a cross-sectional view of a package-on-package having a semiconductor chip 114 mounted on the substrate illustrated in FIG. 1 according to an embodiment of the present invention.

Referring to FIG. 2, a first semiconductor chip 114 is adhered to the upper surface of the flexible substrate 102 using an adhesive tape 120. Alternatively, the semiconductor chip 114 may be adhered to the upper surface of the flexible substrate 102 using liquid epoxy that is hardened for adherence. A bond pad (not shown) on the semiconductor chip 114 is then connected to the first printed circuit pattern 106, which is a bond finger formed on the flexible substrate 102 in this embodiment, using a bonding wire 1118. The upper surface of the flexible substrate 102 may be further sealed by an epoxy mold compound (EMC), as illustrated in FIG. 4. In a similar manner, a second semiconductor chip 116 is adhered to the lower surface of the flexible substrate 102 and wire-bonded to printed circuit patterns. The second semiconductor chip 116 may also be sealed by an EMC, as illustrated in FIG. 4.

In other embodiments, the first and second semiconductor chips 114 and 116 may be sealed with an EMC at the same time after each of the chips 114 and 116 has been respectively adhered to the flexible substrate 102 and wire-bonded to the first printed circuit patterns 106.

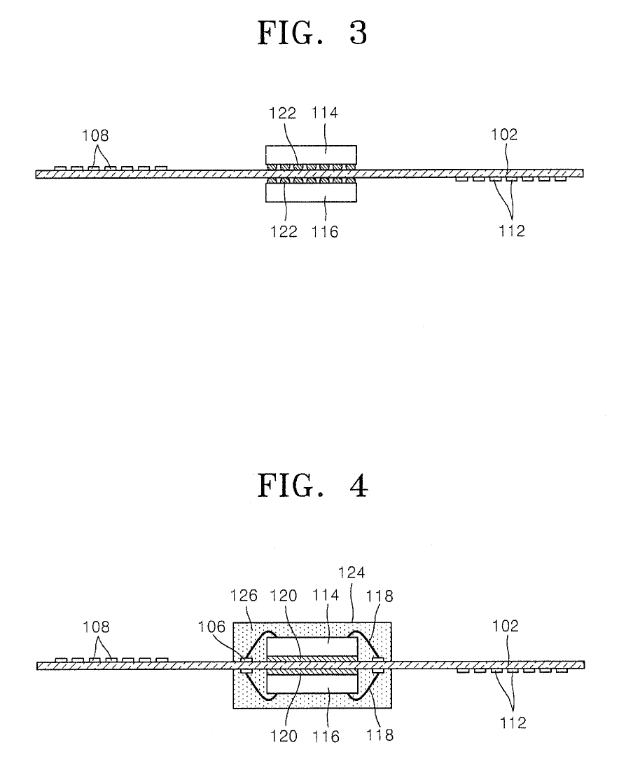

FIG. 3 is a cross-sectional view illustrating a package-on-package having semiconductor chips 114 and 116 mounted on the flexible substrate 102 illustrated in FIG. 1 according to another embodiment of the present invention.

As described above, in the embodiment illustrated in FIG. 2, the first and second semiconductor chips 114 and 116 are adhered using the adhesive tape 120 and connected to the flexible substrate 102 by bonding wire 118. However, in FIG. 3, bumps 122 may be formed on the surfaces of the first and second semiconductor chips 114 and 116 so that the first and second chips 114 and 116 can be directly connected to the first printed circuit pattern 106 formed on the surface of the flexible substrate 102 using flip chip bonding. In the present embodiment, the first printed circuit pattern 106 may be in the form of a land to which the bumps 122 can be connected. The first and second semiconductor chips 114 and 116 mounted on the upper and lower surfaces of the flexible substrate 102 may have the same or different functions as the first and second semiconductor chips 114 and 116 mounted on the upper and lower surfaces of the flexible substrate 102 of FIG. 2.

FIG. 4 illustrates a cross-sectional view of a package body 124 formed by molding the package-on-package illustrated in FIG. 2 according to an embodiment of the present invention.

Referring to FIG. 4, the package-on-package with the first and second semiconductor chips 114 and 116 mounted on the flexible substrate 102 as illustrated in FIG. 2 is molded using an epoxy mold compound (EMC) 126. Although not illustrated in FIG. 4, the first and second semiconductor chips 114 and 116 mounted on the flexible substrate 102 using a flip chip technique as shown in FIG. 3 may be molded in a similar manner using an EMC. As a result, the package body 124 is obtained in which the first printed circuit pattern 106, the bonding wire 118, and the first and second semiconductor chips 114 and 116 are all sealed by the EMC 126. In the present embodiment, the second printed circuit patterns 108A and 108B and third printed circuit pattern 112 are exposed outside of the package body 124. Also in the present embodiment, the second printed circuit patterns 108A and 108B are formed on the left upper surface of the flexible substrate 102, and the third printed circuit pattern 112 is formed on the right lower surface of the flexible substrate 102. Accordingly, even though the first and second semiconductor chips 114 and 116 are encapsulated with the EMC 126, they may still communicate with other devices (not shown) through the electrical connections provided by the bonding wire 118, the first printed circuit pattern 106, the wires 110 and 113, and the second and third printed circuit patterns 108 and 112.

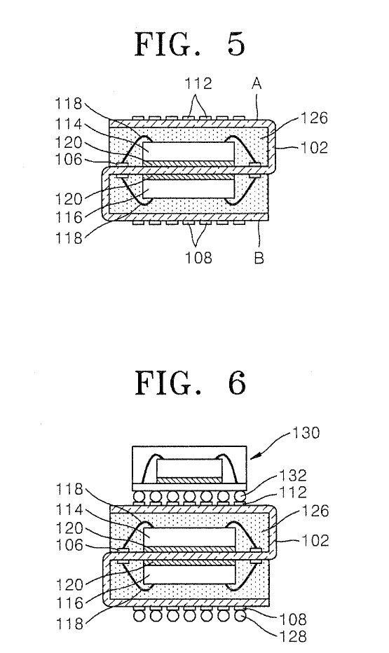

FIG. 5 illustrates a cross-sectional view of portions of the flexible substrate 102 having the second and third printed circuit patterns 108 and 112 bonded on upper and lower surfaces of a package body 124 on a package-on-package according to an embodiment of the present invention.

Referring to FIG. 5, the flexible substrate 102 extending outside of the package body 124 as illustrated in FIG. 4 is bent and adhered to the upper and lower surfaces of the package body 124 using a liquid or solid adhesive agent. Such adhesion of the flexible substrate 102 to the upper and lower surfaces of the package body 124, if necessary, may additionally be strengthened by using thermal compression during or after the adhesion of the flexible substrate 102 to the upper and lower surfaces of the package body 124. Alternatively, the bent portions of the flexible substrate 102 may be adhered to the package body 124 with the EMC 126, by, for example, heating the EMC 126 to predetermined temperature and curing the EMC 126 after the bent portions of the flexible substrate 102 have been applied to the heated EMC 126.

In FIG. 5, a left extended portion B of the flexible substrate 102 having the second printed circuit pattern 108 formed on the upper surface of the flexible substrate 102 is bent towards and adhered to the lower surface of the package body 124, and a right extended portion A of the flexible substrate 102 having the third printed circuit pattern 112 formed on the lower surface of the extended flexible substrate 102 is bent towards and adhered to the upper surface of the package body 124. This configuration insures that the second and third circuit patterns 108 and 112 remain exposed above and below the package body 124.

FIG. 6 is a cross-sectional view illustrating a semiconductor package 130 and a solder ball adhered to a package-on-package according to an embodiment of the present invention.

Referring to FIG. 6, the semiconductor package 130 is mounted on an upper extended surface A of the package-on-package of FIG. 5 having the third printed circuit pattern 112 on the upper extended surface A of the package-on-package. An internal structure of the semiconductor package 130 may be changed in accordance with one skilled in the art. The external connection terminals of the semiconductor package 130 may be adhered to the third printed circuit patterns 112 on the package-on-package with solder balls 132. Additionally, solder balls 128 may be adhered to the second printed circuit pattern 108 for connecting to another exterior device. In other embodiments, however, the semiconductor package 130 may be connected to the second printed circuit pattern 108 through solder balls 128, and the solder balls 132 may be disposed on the third printed circuit pattern 112 to connect to an external device (not shown).

The structure of a package-on-package according to an embodiment of the present invention will now be described with reference to FIGS. 5 and 6.

The package-on-package according to this embodiment of the present invention includes a flexible substrate 102 having first, second, and third printed circuit patterns 106, 108 (108A and 108B), and 112 formed on the upper and lower surfaces of the flexible substrate 100. First and second semiconductor chips 114 and 116 are mounted on the upper and lower surfaces of central portions of the substrate 102 and connected to the first printed circuit pattern 106 through bonding wires 118. A package body 124 is formed for sealing the first and second semiconductor chips 114 and 116 and the first printed circuit pattern 106. A lower extended surface B of the substrate 100 having the second printed circuit pattern 108 formed on the substrate 100 is bent and adhered to a lower surface of the package body 124, and an upper extended surface A of the substrate 100 having the third printed circuit pattern formed on the substrate 100 is bent and adhered to the upper surface of the package body 124.

In the present embodiment, the package-on-package may further include solder balls 128 adhered to the lower extended surface B of the substrate 100. The package-on-package may further include another semiconductor package 130 mounted on the upper extended surface A of the substrate 100 by use of solder balls 132.

Accordingly, as set out by the embodiment of the present invention described above, the semiconductor chips can be mounted on the upper and lower surfaces of the substrate and external connection terminals such as solder balls can be adhered to the upper and lower surfaces of the substrate, thereby increasing the mounting density of the semiconductor package within a limited area.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A method of fabricating a package-on-package, the method comprising:
providing a flexible substrate having a first printed circuit pattern formed on upper and lower surfaces of the flexible substrate, second printed circuit patterns formed on the upper surface of the flexible substrate on a first side of the first printed circuit pattern, and third printed circuit patterns formed on the lower surface of the flexible substrate on a second side opposite the first side, of the first printed circuit pattern;
mounting first and second semiconductor chips respectively on the upper and lower surfaces of the flexible substrate at substantially central portions of the flexible substrate;
sealing the first printed circuit pattern and the first and second semiconductor chips to form a package body, where portions of the flexible substrate having the second and third printed circuit patterns are exposed outside of the package body; bending the exposed portions of the flexible substrate having the second and third printed circuit patterns respectively towards upper and lower surfaces of the package body such that the second and third printed circuit patterns are exposed on the upper and lower surfaces of the package body; and
adhering the flexible substrate having the second and third printed circuit patterns to the upper and lower surfaces of the package body.

2. The method of claim 1, wherein mounting the first and second semiconductor chips respectively on the upper and lower surfaces of the flexible substrate comprises:
bonding the first and second semiconductor chips to chip pads in a substantially central portion of the flexible substrate; and
connecting bond pads of the semiconductor chips to the first printed circuit pattern using a bonding wire.

3. The method of claim 1, wherein mounting the first and second semiconductor chips respectively on the upper and lower surfaces of the flexible substrate comprises directly connecting solder bumps of the semiconductor chips to the first printed circuit pattern.

4. The method of claim 1, wherein the second and third printed circuit patterns are solder ball pads.

5. The method of claim 1, wherein the second printed circuit pattern is formed on the upper surface of the flexible substrate and adhered to the lower surface of the package body.

6. The method of claim 1, wherein the third printed circuit pattern is formed on the lower surface of the flexible substrate and adhered to the upper surface of the package body.

7. The method of claim 1, wherein the first and second semiconductor chips respectively mounted on the upper and lower surfaces of the flexible substrate are of the same type.

8. The method of claim 1, wherein the first and second semiconductor chips respectively mounted on the upper and lower surfaces of the flexible substrate are of different types.

9. The method of claim 1, wherein sealing the first printed circuit pattern and the semiconductor chips comprises sealing the first printed circuit pattern and the semiconductor chips with an epoxy mold compound (EMC).

10. The method of claim 1, further comprising connecting another semiconductor package on the third printed circuit pattern after adhering the flexible substrate having the second and third printed circuit patterns to the upper and lower surfaces of the package body.

11. The method of claim 1, further comprising adhering solder balls to the second printed circuit pattern after adhering the flexible substrate having the second and third printed circuit patterns to the upper and lower surfaces of the package body.

12. The method of claim 1, wherein adhering the flexible substrate having the second and third printed circuit patterns to the upper and lower surfaces of the package body comprises adhering surfaces of the flexible substrate opposite of the surfaces having the second and third printed circuit patterns to the package body using a liquid or solid adhesive agent.

13. The method of claim 12, further comprising performing a thermal compression after adhering the surfaces of the flexible substrate having the second and third printed circuit patterns to the upper and lower surfaces of the package body using the liquid or solid adhesive agent.

14. A package-on-package comprising:
a flexible substrate having first, second, and third printed circuit patterns formed on upper and lower surfaces of the flexible substrate;
first and second semiconductor chips respectively mounted on the upper and lower surfaces of the flexible substrate at a substantially central portion of the flexible substrate, the first and second semiconductor chips connected to the first printed circuit pattern; and
a package body sealing the semiconductor chips and the first printed circuit pattern,
wherein a portion of the flexible substrate having the second printed circuit pattern is bent and adhered to a lower surface of the package body, and
wherein a portion of the flexible substrate having the third printed circuit pattern is bent and adhered to an upper surface of the package body.

15. The package-on-package of claim 14, further comprising solder balls adhered to the second printed circuit pattern.

16. The package-on-package of claim 14, further comprising another semiconductor package mounted on the third printed circuit pattern.

17. The package-on-package of claim 16, wherein the semiconductor package mounted to the third printed circuit pattern has external connection terminals as solder balls.

18. The package-on-package of claim 14, wherein the first printed circuit pattern and the semiconductor chips are connected to each other by solder bumps.

19. The package-on-package of claim 14, wherein the first printed circuit pattern and the semiconductor chips are connected to each other by bonding wires.

20. The package-on-package of claim 14, wherein the first, second, and third printed circuit patterns are electrically connected to each other in the flexible substrate.
